(19) United States
(12) Patent Application Publication
(10) Pub. No.: US 2026/0063687 A1
(43) Pub. Date: Mar. 5, 2026

(54) ELECTRICAL MONITORING DEVICES AND RELATED METHODS

(71) Applicant: ABB SCHWEIZ AG, Baden (CH)

(72) Inventors: Huangjie Gong, Raleigh, NC (US); Matthew Hetrich, Cary, NC (US); Abhinav Patni, Raleigh, NC (US); Sheng Zhong, Hillsborough, NC (US)

(21) Appl. No.: 18/822,949

(22) Filed: Sep. 3, 2024

(51) Int. Cl. G01R 19/25; G01R 21/133

(52) U.S. Cl. CPC G01R 19/25; G01R 21/133

(57) ABSTRACT

Electrical monitoring devices may include a main power connection for transmitting electrical power to a disconnect panel, an auxiliary power connection for transmitting electrical power to an auxiliary device, and a data collection and communication module. The data collection and communication module may include at least one main sensor for sensing at least one first electrical characteristic of the main power connection, at least one auxiliary sensor for sensing at least one second electrical characteristic of the auxiliary power connection, and a communication module for communicating information based on the at least one first electrical characteristic and the at least one second electrical characteristic to a user device. Various other related systems and methods may employ such electrical monitoring devices.

### BACKGROUND

The increasing popularity of electric vehicles (EVs) and other auxiliary electrical devices has led to a rise in energy use in homes. This higher energy usage, including from homes with EV chargers, can benefit from electrical power data monitoring. Such monitoring systems may be helpful in comprehending energy use patterns and improving overall consumption. The data obtained can offer homeowners useful details about their energy use, allowing them to better control power and balance between everyday electricity needs and auxiliary demands (EV charging demands). Higher energy bills can often result from increased electrical loads, making power data monitoring a helpful consideration for homeowners who have auxiliary electrical needs. These monitoring systems can also support utility companies in handling grid load more efficiently, helping avoid power outages or fluctuations that could disrupt service.

### SUMMARY

In some aspects, the techniques described herein relate to an electrical monitoring device, including: a main power connection for transmitting electrical power to a disconnect panel; an auxiliary power connection for transmitting electrical power to an auxiliary device; and a data collection and communication module, including: at least one main sensor for sensing at least one first electrical characteristic of the main power connection; at least one auxiliary sensor for sensing at least one second electrical characteristic of the auxiliary power connection; and a communication module for communicating information based on the at least one first electrical characteristic and the at least one second electrical characteristic to a user device.

In some aspects, the techniques described herein relate to a device, wherein the communication module includes an antenna for wirelessly communicating the information to the user device.

In some aspects, the techniques described herein relate to a device, wherein the communication module includes a wired connection for communicating the information to the user device.

In some aspects, the techniques described herein relate to a device, wherein: the at least one main sensor includes a first current sensor for sensing an electrical current in the main power connection; and the at least one auxiliary sensor includes a second current sensor for sensing an electrical current in the auxiliary power connection.

In some aspects, the techniques described herein relate to a device, wherein each of the at least one main sensor and the at least one auxiliary sensor includes at least one of: an inductive sensor; a current shunt sensor; a Hall effect-based sensor; a fluxgate sensor; or a Rogowski principle-based sensor.

In some aspects, the techniques described herein relate to a device, wherein the auxiliary device includes at least one of: an electric vehicle charging station; an electric vehicle; a pump; an air conditioning unit; a heater; or a refrigerator.

In some aspects, the techniques described herein relate to a device, wherein the data collection and communication module further includes an analog-to-digital converter for converting analog signals from the at least one main sensor and from the at least one auxiliary sensor to digital signals.

In some aspects, the techniques described herein relate to a device, wherein the data collection and communication module is integrated in or on a printed circuit board.

In some aspects, the techniques described herein relate to a device, further including an auxiliary disconnect along the auxiliary power connection.

In some aspects, the techniques described herein relate to a device, wherein the disconnect panel includes a residential breaker panel.

In some aspects, the techniques described herein relate to a device, further including a power input for receiving electrical power from a utility grid.

In some aspects, the techniques described herein relate to an electrical monitoring device, including: a main power connection for transmitting electrical power to a disconnect panel; an auxiliary power connection for transmitting electrical power to an auxiliary device; at least one main sensor for sensing at least one first electrical characteristic of the main power connection; at least one auxiliary sensor for sensing at least one second electrical characteristic of the auxiliary power connection; an analog-to-digital converter for converting analog signals from the at least one main sensor and from the at least one auxiliary sensor to digital signals; and a communication module for communicating information based on the at least one first electrical characteristic and the at least one second electrical characteristic to a user device.

In some aspects, the techniques described herein relate to a device, further including an antenna coupled to the communication module and configured to wirelessly communicate the information to the user device.

In some aspects, the techniques described herein relate to a device, further including a power input for receiving electrical power from a power meter.

In some aspects, the techniques described herein relate to a device, wherein the auxiliary device includes an electric vehicle charging station.

In some aspects, the techniques described herein relate to a device, wherein: each of the at least one main sensor and the at least one auxiliary sensor includes a current sensor; and the information includes at least one of: electrical current information; electrical power information; electrical voltage information; or electrical energy usage information.

In some aspects, the techniques described herein relate to a device, wherein: the main power connection includes a main three-wire output including a main hot wire output and the auxiliary power connection includes an auxiliary three-wire output including an auxiliary hot wire; and the at least one main sensor is coupled to the main hot wire and the at least one auxiliary sensor is coupled to the auxiliary hot wire.

In some aspects, the techniques described herein relate to a method of forming an electrical monitoring device, the method including: coupling at least one main sensor to a main power connection to sense at least one first electrical characteristic of the main power connection and to generate main sensor data; coupling at least one auxiliary sensor to an auxiliary power connection to sense at least one second electrical characteristic of the auxiliary power connection and to generate auxiliary sensor data; coupling an analog-to-digital converter to the at least one main sensor and to the at least one auxiliary sensor for converting the main sensor data and the auxiliary sensor data from analog data to digital data; and coupling a communication module to the analog-to-digital convert for communicating information based on the converted main sensor data and auxiliary sensor data to a user device.

In some aspects, the techniques described herein relate to a method, wherein: coupling the at least one main sensor to the main power connection includes coupling a main current sensor to the main power connection; and coupling the at least one auxiliary sensor to the auxiliary power connection includes coupling an auxiliary current sensor to the auxiliary power connection.

In some aspects, the techniques described herein relate to a method, further including coupling an antenna to the communication module to wirelessly communicate the information to the user device.

### BRIEF DESCRIPTION OF THE DRAWINGS

FIG. 1 is a schematic diagram of a power supply system that includes an electrical monitoring device, according to at least one embodiment of the present disclosure.

FIG. 2 is a schematic diagram of a power supply system that includes an electrical monitoring device, according to at least one additional embodiment of the present disclosure.

FIG. 3 is a schematic diagram of a power supply system that includes an electrical monitoring device, according to at least one further embodiment of the present disclosure.

FIG. 4 is a schematic diagram of an electrical monitoring device, according to at least one embodiment of the present disclosure.

FIG. 5 is a flow diagram illustrating a method of operating an electrical monitoring device, according to at least one embodiment of the present disclosure.

FIG. 6 is a flow diagram illustrating a method of forming an electrical monitoring device, according to at least one embodiment of the present disclosure.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE EMBODIMENTS

The present disclosure provides detailed descriptions of power supply systems that include electrical monitoring devices. As will be explained in greater detail below, embodiments of the present disclosure may include electrical monitoring devices that may be configured to collect data related to energy usage to a main disconnect panel (e.g., a residential breaker panel, a commercial breaker panel, a fuse box, a fusible switch box, a protective relay panel, etc.) and related to energy usage to an auxiliary device, such as an EV charger. The electrical monitoring devices of the present disclosure may be configured to communicate information based on this energy data to a user device. Such devices may be capable of monitoring electrical energy use regardless of the type of auxiliary device to enable consumers and utility service providers to analyze and make decisions based on the information.

Features from any of the embodiments described herein may be used in combination with one another in accordance with the general principles described herein. These and other embodiments, features, and advantages will be more fully understood upon reading the following detailed description in conjunction with the accompanying drawings and claims.

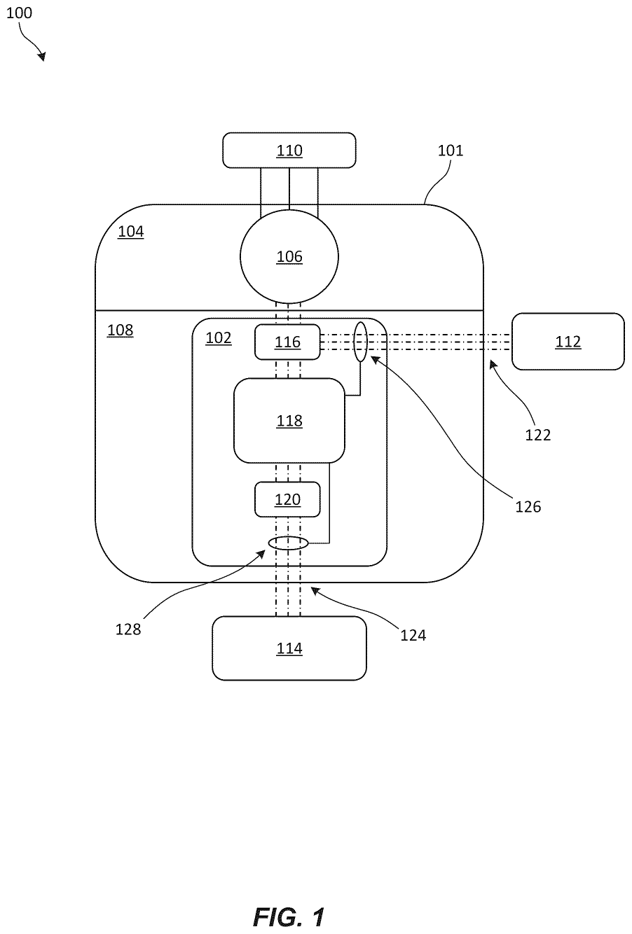

FIG. 1 is a schematic view of a power supply system 100 that includes an electrical monitoring device 102, according to at least one embodiment of the present disclosure. The power supply system 100 may be in the form of an expanded meter socket 101 that includes the electrical monitoring device 102.

For example, the power supply system 100 may include a meter socket section 104 that houses a power meter 106 and a power monitoring section 108 that houses the electrical monitoring device 102. In some embodiments, the meter socket section 104 may be locked or otherwise access-limited (e.g., for access only by personnel authorized by a power company), such as to inhibit tampering and/or theft of electrical power and for safety. The power monitoring section 108 may be accessible by a user and/or electrician (e.g., without authorization by a power company), such as for installation, maintenance, modification, etc.

The power supply system 100 may be connected at an input side to a utility grid 110 for providing power to the power supply system 100, through the electrical monitoring device 102, and ultimately to a user's electrical systems, such as to a disconnect panel 112 (e.g., a residential breaker panel, a commercial breaker panel, a fuse box, a fusible switch box, a protective relay panel, etc.) and/or to an auxiliary device 114. In the example shown in FIG. 1, the utility grid 110 may provide a single phase (e.g., three-wire) alternating current (AC) power supply including at least a hot wire and a neutral wire. In additional examples, the utility grid 110 may be a two-wire AC power supply or a four-wire AC power supply. The AC power supply from the utility grid 110 may be a single-phase (e.g., split-phase) AC power supply or a three-phase AC power supply.

Power from the utility grid 110 may pass through the power meter 106 for measuring total electrical power usage through the disconnect panel 112 and the auxiliary device 114. An output side of the power meter 106 may be operably connected to a power input of the electrical monitoring device 102, such as via suitable conductors (e.g., cables, wires, traces, etc.).

The electrical monitoring device 102 may include an input disconnect 116, a data collection and communication module 118, and an auxiliary disconnect 120. A main power connection 122 of the electrical monitoring device 102 may be capable of transmitting electrical power from the electrical monitoring device 102 to the disconnect panel 112. An auxiliary power connection 124 of the electrical monitoring device 102 may be capable of transmitting electrical power from the electrical monitoring device 102 to and/or from the auxiliary device 114.

The input disconnect 116 may be positioned between the power meter 106 and the data collection and communication module 118 and between the power meter 106 and the disconnect panel 112. In some embodiments, the input disconnect 116 may be rated with a sufficiently high amperage to supply full power to both the disconnect panel 112 and the auxiliary device 114. In other words, the current rating of the input disconnect 116 may be at least as high as the combination of the disconnect panel 112 rating and of the auxiliary device 114 rating, such as to reduce instances of the input disconnect 116 inadvertently opening and halting service to both the disconnect panel 112 and to the auxiliary device 114.

The auxiliary disconnect 120 may be positioned between the data collection and communication module 118 and the auxiliary device 114. The auxiliary disconnect 120 may be configured to interrupt service to or from the auxiliary device 114 for installation or maintenance, in case of a fault (e.g., short-circuit) in the auxiliary device 114, for installation or maintenance of the data collection and communication module 118, etc.

As will be explained further below, the data collection and communication module 118 may be configured to sense at least one first electrical characteristic of the main power connection 122 and at least one second electrical characteristic of the auxiliary power connection 124. For example, the electrical monitoring device 102 may include at least one main sensor 126 for sensing the first electrical characteristic of the main power connection 122 and at least one auxiliary sensor 128 for sensing the second electrical characteristic of the auxiliary power connection 124. Byway of example and not limitation, each of the at least one main sensor 126 and the at least one auxiliary sensor 128 may be in the form of an inductive sensor, a current shunt sensor, a Hall effect-based sensor, a fluxgate sensor, and/or a Rogowski principle-based sensor (e.g., a Rogowski coil sensor). The data collection and communication module 118 may be in the form of a printed circuit board (PCB) that includes at least an analog-to-digital converter for processing signals from the at least one main sensor 126 and at least one auxiliary sensor 128 and at least a communication module for communicating information based on the signals to a user device or other recipient. One or more of these components of the data collection and communication module 118 may be implemented via one or more microprocessors, signal processing components, transistors, transceivers, etc.

In some examples, relational terms, such as “first,” “second,” etc., may be used for clarity and convenience in understanding the disclosure and accompanying drawings and do not connote or depend on any specific preference, orientation, or order, except where the context clearly indicates otherwise.

In some embodiments, the first electrical characteristic and the second electrical characteristic may include current and/or voltage, and/or a characteristic derived from current and/or voltage (e.g., power). The data collection and communication module 118 may also be configured to communicate the first and second electrical characteristic, or information based on the first and second electrical characteristic, to a user device or other recipient. For example, the main sensor 126 may be or include a first current sensor for sensing an electrical current in the main power connection 122 and the auxiliary sensor 128 may be or include a second current sensor for sensing an electrical current in the auxiliary power connection 124.

The auxiliary device 114 may be one or more devices that use electrical power. Examples of the auxiliary device 114 include an electric vehicle (EV) charging station, an electric vehicle, a pump, an air conditioning unit, a heater, a refrigerator. Other devices that draw electrical power may also be considered auxiliary devices 114. In additional embodiments of the present disclosure, the auxiliary device 114 may generate electricity, and the auxiliary power connection 124 may operate as an input, such as for providing electrical power to the disconnect panel 112. For example, the auxiliary device 114 may be or include a wind turbine, a water turbine, a thermal power generator, a gas generator, a solar panel, etc. In some embodiments, an EV may include sufficient onboard circuitry and components to charge and/or discharge by connecting to a standard (e.g., 110V, 115V, 120V, 208V, 220V, 230V, 240V, etc.) electrical outlet without a separate EV charging station. Examples of such EVs may function as a current load or as a current source. Accordingly, the at least one auxiliary sensor 128 can, in some embodiments, be used to obtain power data regardless of the direction that electrical current flows in the auxiliary power connection 124.

FIG. 1 illustrates a single auxiliary device 114. However, the present disclosure is not so limited. In additional examples, the auxiliary device 114 may represent multiple auxiliary devices 114 connected to the electrical monitoring device 102.

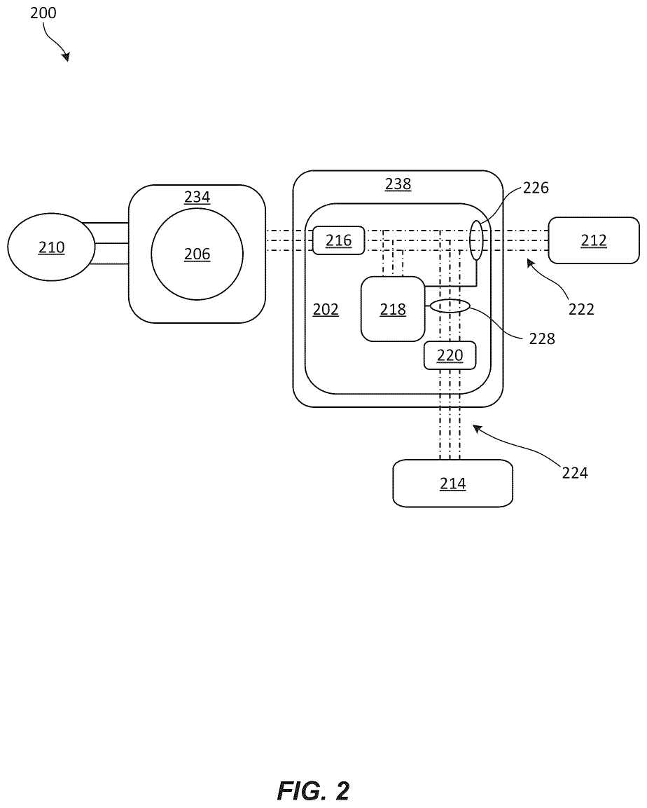

FIG. 2 is a schematic view of a power supply system 200 that includes an electrical monitoring device 202, according to at least one additional embodiment of the present disclosure.

In some respects, the power supply system 200 of FIG. 2 may be similar to the power supply system 100 illustrated in FIG. 1. For example, the power supply system 200 of FIG. 2 may include a power meter 206 that receives electrical power from a utility grid 210, a disconnect panel 212 and an auxiliary device 214, and the electrical monitoring device 202 that is configured to monitor electrical characteristics of a main power connection 222 to the disconnect panel 212 and of an auxiliary power connection 224 to the auxiliary device 214, such as via a main sensor 226 and/or an auxiliary sensor 228. The electrical monitoring device 202 may include an input disconnect 216, a data collection and communication module 218, and an auxiliary disconnect 220.

Referring to FIG. 2, the power supply system 200 may include a meter socket 234 containing the power meter 206 that is physically separate from a housing 238 that contains the electrical monitoring device 202. In some examples, the housing 238 and electrical monitoring device 202 therein may be mounted adjacent to (e.g., along a same wall as) the meter socket 234. In additional examples, the housing 238 and electrical monitoring device 202 may be mounted remotely from the meter socket 234, such as adjacent to the auxiliary device 214 or adjacent to the disconnect panel 212.

Accordingly, referring to FIGS. 1 and 2, electrical monitoring devices 102, 202 of the present disclosure may be implemented as part of an expanded meter socket 101 or via a housing 238 that is separate from a meter socket 234. The functional components of the electrical monitoring devices 102, 202 may be the same or similar in either case.

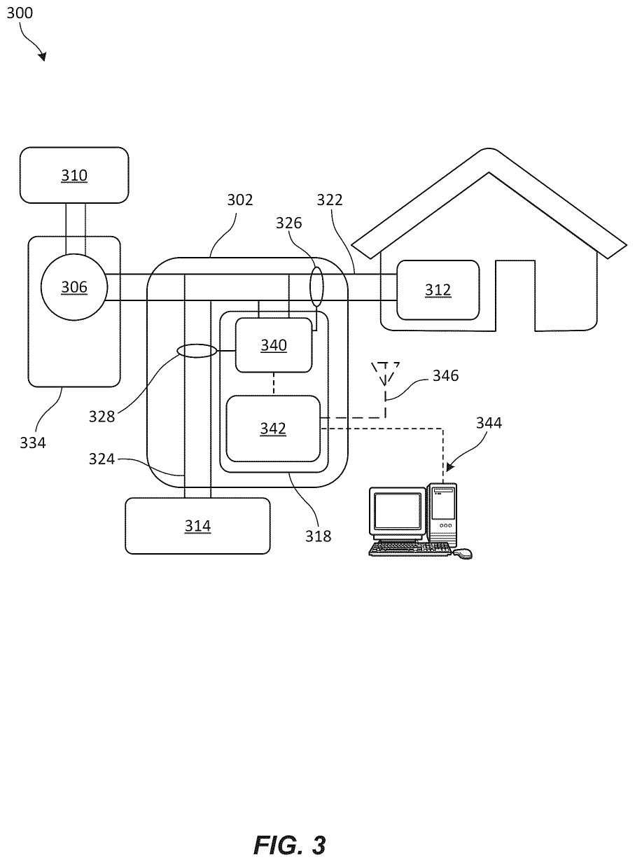

FIG. 3 is a schematic diagram of a power supply system 300 that includes an electrical monitoring device 302, according to at least one further embodiment of the present disclosure.

In some respects, the power supply system 300 of FIG. 3 may be similar to the power supply system 100 of FIG. 1 and/or to the power supply system 200 of FIG. 2. For example, the power supply system 300 may include a power meter 306 that receives electrical power from a utility grid 310, a disconnect panel 312 and an auxiliary device 314 (e.g., an electric vehicle charging station, an electric vehicle, a pump, an air conditioning unit, a heater, a refrigerator, etc.). The power supply system 300 may also include the electrical monitoring device 302, which may be configured to monitor electrical characteristics of a main power connection 322 to the disconnect panel 312 and of an auxiliary power connection 324 to the auxiliary device 314. The electrical monitoring device 302 may include a data collection and communication module 318.

The electrical monitoring device 302 may be housed in an expanded meter socket, such as the expanded meter socket 101 (FIG. 1), or the electrical monitoring device 302 may be housed in a housing separate from a meter socket, such as the housing 238 of FIG. 2.

Referring to FIG. 3, the data collection and communication module 318 may include a data collection module 340 and a communication module 342. The data collection module 340 may be configured to receive data representative of at least one first electrical characteristic (e.g., current, voltage) of the main power connection 322 from at least one main sensor 326 coupled to the main power connection 322. The data collection module 340 may also be configured to receive data representative of at least one second electrical characteristic (e.g., current, voltage) of the auxiliary power connection 324 from at least one auxiliary sensor 328 coupled to the auxiliary power connection 324. In some examples, the data collection module 340 may include an analog-to-digital converter to convert analog data from the main sensor 326 and/or auxiliary sensor 328 to digital data.

The communication module 342 may be configured to receive information based on the at least one first electrical characteristic and the at least one second electrical characteristic from the data collection module 340. The communication module 342 may also be configured to communicate that information to a user device 344 or other recipient. By way of example and not limitation, the user device 344 or other recipient may be a personal computer, a mobile device (e.g., a mobile phone, a tablet, etc.), a laptop computer, a data storage device, a smart television, a smart speaker, a server, a network (e.g., a cellular network, the internet, a local area network (LAN), etc.), an external local controller, etc. The user device may be a device controlled by a consumer of the energy (e.g., a homeowner or a business owner), or a device controlled by a provider of the energy (e.g., a utility service provider).

The communication module 342 may communicate the information to the user device 344 via a wired connection, a wireless connection, or a combination thereof. In the case of a wireless connection, in some examples the electrical monitoring device 302 may include an antenna 346. In some embodiments, the antenna 346 may physically extend outside of a housing containing the data collection and communication module 318, such as to avoid or inhibit signal shielding that may otherwise be caused by the housing.

Although illustrated as separate elements, the data collection module 340 and the communication module 342 may represent portions of a single module or application. In addition, in certain embodiments one or more of these modules may represent one or more software applications or programs that, when executed by one or more computing devices, may cause the computing device(s) to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

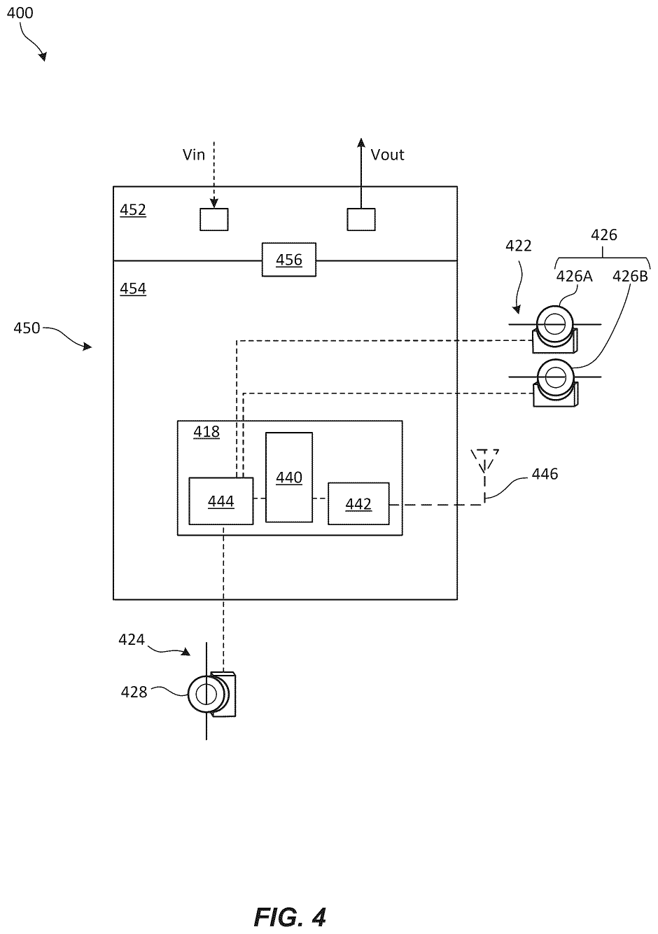

FIG. 4 is a schematic diagram of an electrical monitoring device 400, according to at least one embodiment of the present disclosure. In some examples, the electrical monitoring device 400 may be implemented or employed as any of the electrical monitoring devices 102, 202, 302 described above.

The electrical monitoring device 400 may include a data collection and communication module 418, which may be implemented in one or more microcontrollers and/or separate modules. The data collection and communication module 418 may include a data collection module 440 and a communication module 442. The data collection module 440 may receive data from at least one main sensor 426 (e.g., a first main sensor 426A and a second main sensor 426B) coupled to a main power connection 422. In the example illustrated in FIG. 4, the main power connection 422 may be configured for split-phase power. The first main sensor 426A may be coupled to a hot wire associated with a first AC phase and the second main sensor 426B may be coupled to a hot wire associated with a second AC phase. In additional embodiments, a single main sensor 426 or more than two main sensors 426 may be employed. The first main sensor 426A and the second main sensor 426B may be configured to sense one or more electrical characteristics (e.g., current, voltage) of the main power connection 422.

The data collection module 440 may also receive data from at least one auxiliary sensor 428. Only one auxiliary sensor 428 is illustrated in FIG. 4. However, the present disclosure is not so limited. In additional embodiments, multiple auxiliary sensors 428 may be used. The at least one auxiliary sensor 428 may be coupled to an auxiliary power connection 424, such as a hot wire of the auxiliary power connection 424. The at least one auxiliary sensor 428 may be configured to sense at least one electrical characteristic (e.g., current, voltage) of the auxiliary power connection 424.

The data collection and communication module 418 may also include an analog-to-digital converter 444 for converting analog signals from the at least one main sensor 426 and from the at least one auxiliary sensor 428 to digital signals. The data collection module 440 may receive the digital signals from the analog-to-digital converter 444 and may pass information based on the digital signals to the communication module 442 for communication to a user device, such as via a wired connection or a wireless connection (e.g., via an antenna 446).

As illustrated in FIG. 4, in some examples of the present disclosure, the electrical monitoring device 400 may include one or more printed circuit boards (PCBs). For example, a main PCB 450 may support the data collection and communication module 418. The main PCB 450 may include a high-voltage PCB 452 (e.g., including a high-voltage power plane, such as a 240 VAC power plane) and a low-voltage PCB 454 (e.g., including one or more low-voltage power planes, such as a 5 V power plane, a 3.3 V power plane, and a ground power plane). The high-voltage PCB 452 may be operably coupled to the low-voltage PCB 454 by an attenuator 456, which may act as a low-voltage power source for the low-voltage PCB 454.

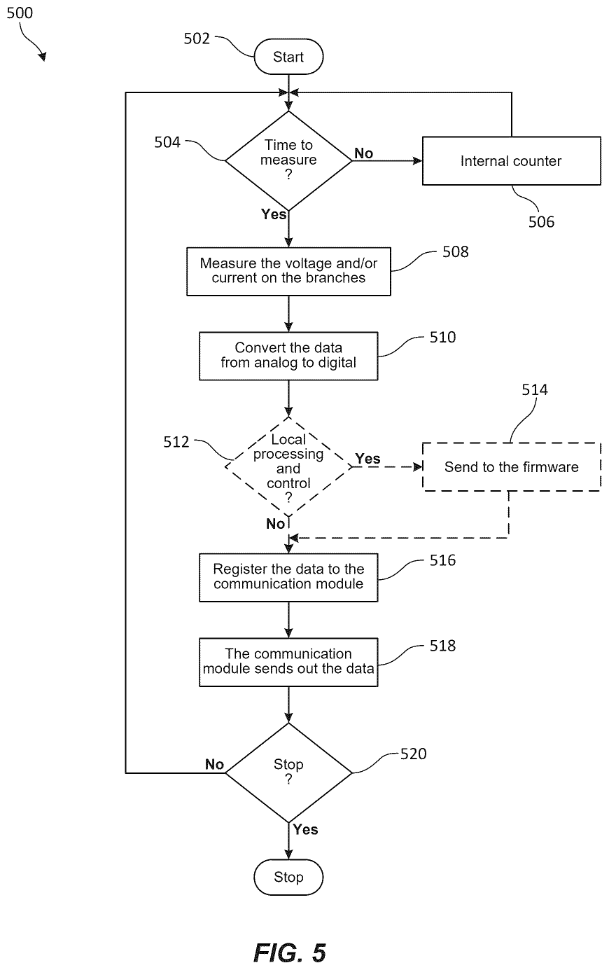

FIG. 5 is a flow diagram illustrating a method 500 of operating an electrical monitoring device (e.g., any of the electrical monitoring devices 102, 202, 302, 400 described above), according to at least one embodiment of the present disclosure.

At operation 502, the method 500 starts. At operation 504, the device determines whether it is time for measurement. By way of example, a user may set a time resolution for the measurement, such as every second, every ten seconds, every thirty seconds, every minute, etc. If it is not time for measurement, an internal counter 506 may be advanced and operation 504 may be repeated to determine whether the advanced time has reached a time for measurement. If it is time for measurement, the method 500 may progress by performing operation 508 to measure at least one electrical characteristic of one or more branches (e.g., of a main power connection and/or of an auxiliary power connection). For example, voltage and/or current may be measured by one or more sensors.

At step 510, the measurement data may be converted from analog to digital, such as by an analog-to-digital converter. Optionally, if the device includes firmware for processing and control, at operation 512 the digital data may be sent to the firmware 514 for the processing and control. Either the data processed by the firmware, or in the absence of firmware, the data from the analog-to-digital converter may be sent to and registered in a communication module at operation 516.

At operation 518, the communication module may send the data, or information based on the data, to a user device. At operation 520, the electrical monitoring device may determine whether the method 500 should stop. If the method 500 should continue, such as to collect and communicate more data, then the method may be repeated from operation 504 to again determine if it is time to take measurements.

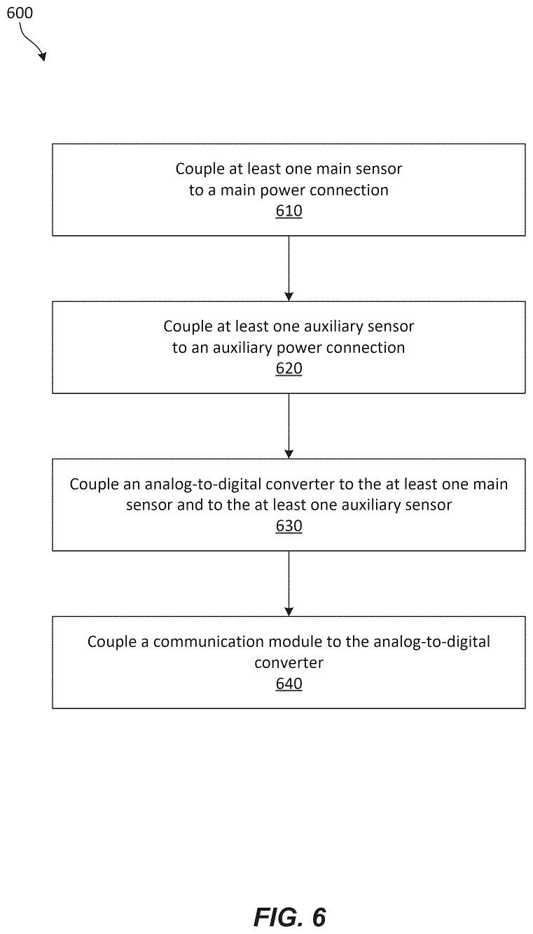

FIG. 6 is a flow diagram illustrating a method 600 of forming an electrical monitoring device, according to at least one embodiment of the present disclosure.

At operation 610, at least one main sensor may be coupled to a main power connection to sense at least one first electrical characteristic of the main power connection and to generate main sensor data. Operation 610 may be performed in a variety of ways. For example, a current sensor and/or a voltage sensor may be coupled to a hot wire of the main power connection that is connected upstream to a disconnect panel, such as a residential breaker panel.

At operation 620, at least one auxiliary sensor may be coupled to an auxiliary power connection to sense at least one second electrical characteristic of the auxiliary power connection and to generate auxiliary sensor data. Operation 620 may be performed in a variety of ways. For example, a current sensor and/or a voltage sensor may be coupled to a hot wire of an auxiliary power connection that is connected to an auxiliary device, such as an EV charging station.

At operation 630, an analog-to-digital converter may be coupled to the at least one main sensor and to the at least one auxiliary sensor data for converting the main sensor data and the auxiliary sensor data from analog data to digital data. For example, the main sensor data and the auxiliary sensor data may be generated in an analog form. The analog-to-digital converter may convert the analog data to digital data for further processing, storage, and communication. The analog-to-digital converter may be a standalone element, or a portion of a larger element or module, such as a microcontroller.

At operation 640, a communication module may be coupled to the analog-to-digital converter for communicating information based on the converted main sensor data and auxiliary sensor data to a user device. For example, the communication module may be configured to communicate wirelessly and/or via a wired connection to a user device. The communication module may be a standalone element, or a portion of a larger element or module, such as a microcontroller.

Accordingly, the present disclosure includes electrical monitoring devices and related methods that may be improved in some respects over existing solutions. For example, some embodiments of the present disclosure may be able to monitor and/or communicate information related to electrical power usage of auxiliary devices, regardless of the type, model, or function of the auxiliary device. The devices and methods of the present disclosure may be capable of monitoring energy usage in individual power lines over time to enable a user to better understand and/or manage their energy use.

The following example embodiments are also included in the present disclosure.

Example 1. An electrical monitoring device, including: a main power connection for transmitting electrical power to a disconnect panel; an auxiliary power connection for transmitting electrical power to an auxiliary device; and a data collection and communication module, including: at least one main sensor for sensing at least one first electrical characteristic of the main power connection; at least one auxiliary sensor for sensing at least one second electrical characteristic of the auxiliary power connection; and a communication module for communicating information based on the at least one first electrical characteristic and the at least one second electrical characteristic to a user device.

Example 2. The device of Example 1, wherein the communication module includes an antenna for wirelessly communicating the information to the user device.

Example 3. The device of Example 1 or Example 2, wherein the communication module includes a wired connection for communicating the information to the user device.

Example 4. The device of any one of Examples 1 through 3, wherein: the at least one main sensor includes a first current sensor for sensing an electrical current in the main power connection; and the at least one auxiliary sensor includes a second current sensor for sensing an electrical current in the auxiliary power connection.

Example 5. The device of any one of Examples 1 through 4, wherein each of the at least one main sensor and the at least one auxiliary sensor includes at least one of: an inductive sensor; a current shunt sensor; a Hall effect-based sensor; a fluxgate sensor; or a Rogowski principle-based sensor.

Example 6. The device of any one of Examples 1 through 5, wherein the auxiliary device includes at least one of: an electric vehicle charging station; an electric vehicle, a pump; an air conditioning unit; a heater; or a refrigerator.

Example 7. The device of any one of Examples 1 through 6, wherein the data collection and communication module further includes an analog-to-digital converter for converting analog signals from the at least one main sensor and from the at least one auxiliary sensor to digital signals.

Example 8. The device of any one of Examples 1 through 7, wherein the data collection and communication module is integrated in or on a printed circuit board.

Example 9. The device of any one of Examples 1 through 8, further including an auxiliary disconnect along the auxiliary power connection.

Example 10. The device of any one of Examples 1 through 9, wherein the disconnect panel includes a residential breaker panel.

Example 11. The device of any one of Examples 1 through 10, further including a power input for receiving electrical power from a utility grid.

Example 12. An electrical monitoring device, including: a main power connection for transmitting electrical power to a disconnect panel; an auxiliary power connection for transmitting electrical power to an auxiliary device; at least one main sensor for sensing at least one first electrical characteristic of the main power connection; at least one auxiliary sensor for sensing at least one second electrical characteristic of the auxiliary power connection; an analog-to-digital converter for converting analog signals from the at least one main sensor and from the at least one auxiliary sensor to digital signals; and a communication module for communicating information based on the at least one first electrical characteristic and the at least one second electrical characteristic to a user device.

Example 13. The device of Example 12, further including an antenna coupled to the communication module and configured to wirelessly communicate the information to the user device.

Example 14. The device of Example 12 or Example 13, further including a power input for receiving electrical power from a power meter.

Example 15. The device of any one of Examples 12 through 14, wherein the auxiliary device includes an electric vehicle charging station.

Example 16. The device of any one of Examples 12 through 15, wherein: each of the at least one main sensor and the at least one auxiliary sensor includes a current sensor; and the information includes at least one of: electrical current information; electrical power information; electrical voltage information; or electrical energy usage information.

Example 17. The device of any one of Examples 12 through 16, wherein: the main power connection includes a main three-wire output including a main hot wire output and the auxiliary power connection includes an auxiliary three-wire output including an auxiliary hot wire; and the at least one main sensor is coupled to the main hot wire and the at least one auxiliary sensor is coupled to the auxiliary hot wire.

Example 18. A method of forming an electrical monitoring device, the method including: coupling at least one main sensor to a main power connection to sense at least one first electrical characteristic of the main power connection and to generate main sensor data; coupling at least one auxiliary sensor to an auxiliary power connection to sense at least one second electrical characteristic of the auxiliary power connection and to generate auxiliary sensor data; coupling an analog-to-digital converter to the at least one main sensor and to the at least one auxiliary sensor for converting the main sensor data and the auxiliary sensor data from analog data to digital data; and coupling a communication module to the analog-to-digital convert for communicating information based on the converted main sensor data and auxiliary sensor data to a user device.

Example 19. The method of Example 18, wherein: coupling the at least one main sensor to the main power connection includes coupling a main current sensor to the main power connection; and coupling the at least one auxiliary sensor to the auxiliary power connection includes coupling an auxiliary current sensor to the auxiliary power connection.

Example 20. The method of Example 18 or Example 19, further including coupling an antenna to the communication module to wirelessly communicate the information to the user device.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An electrical monitoring device, comprising:
a main power connection for transmitting electrical power to a disconnect panel;
an auxiliary power connection for transmitting electrical power to an auxiliary device; and
a data collection and communication module, comprising:
at least one main sensor for sensing at least one first electrical characteristic of the main power connection;
at least one auxiliary sensor for sensing at least one second electrical characteristic of the auxiliary power connection; and
a communication module for communicating information based on the at least one first electrical characteristic and the at least one second electrical characteristic to a user device.

2. The device of claim 1, wherein the communication module comprises an antenna for wirelessly communicating the information to the user device.

3. The device of claim 1, wherein the communication module comprises a wired connection for communicating the information to the user device.

4. The device of claim 1, wherein:
the at least one main sensor comprises a first current sensor for sensing an electrical current in the main power connection; and
the at least one auxiliary sensor comprises a second current sensor for sensing an electrical current in the auxiliary power connection.

5. The device of claim 1, wherein each of the at least one main sensor and the at least one auxiliary sensor comprises at least one of:
an inductive sensor;
a current shunt sensor;
a Hall effect-based sensor;
a fluxgate sensor; or
a Rogowski principle-based sensor.

6. The device of claim 1, wherein the auxiliary device comprises at least one of:
an electric vehicle charging station;
an electric vehicle;
a pump;
an air conditioning unit;
a heater; or
a refrigerator.

7. The device of claim 1, wherein the data collection and communication module further comprises an analog-to-digital converter for converting analog signals from the at least one main sensor and from the at least one auxiliary sensor to digital signals.

8. The device of claim 1, wherein the data collection and communication module is integrated in or on a printed circuit board.

9. The device of claim 1, further comprising an auxiliary disconnect along the auxiliary power connection.

10. The device of claim 1, wherein the disconnect panel comprises a residential breaker panel.

11. The device of claim 1, further comprising a power input for receiving electrical power from a utility grid.

12. An electrical monitoring device, comprising:
a main power connection for transmitting electrical power to a disconnect panel;
an auxiliary power connection for transmitting electrical power to an auxiliary device;
at least one main sensor for sensing at least one first electrical characteristic of the main power connection;
at least one auxiliary sensor for sensing at least one second electrical characteristic of the auxiliary power connection
an analog-to-digital converter for converting analog signals from the at least one main sensor and from the at least one auxiliary sensor to digital signals; and
a communication module for communicating information based on the at least one first electrical characteristic and the at least one second electrical characteristic to a user device.

13. The device of claim 12, further comprising an antenna coupled to the communication module and configured to wirelessly communicate the information to the user device.

14. The device of claim 12, further comprising a power input for receiving electrical power from a power meter.

15. The device of claim 12, wherein the auxiliary device comprises an electric vehicle charging station.

16. The device of claim 12, wherein:
each of the at least one main sensor and the at least one auxiliary sensor comprises a current sensor; and
the information comprises at least one of: electrical current information; electrical power information; electrical voltage information; or electrical energy usage information.

17. The device of claim 12, wherein:
the main power connection comprises a main three-wire output including a main hot wire output and the auxiliary power connection comprises an auxiliary three-wire output including an auxiliary hot wire; and
the at least one main sensor is coupled to the main hot wire and the at least one auxiliary sensor is coupled to the auxiliary hot wire.

18. A method of forming an electrical monitoring device, the method comprising:
coupling at least one main sensor to a main power connection to sense at least one first electrical characteristic of the main power connection and to generate main sensor data;
coupling at least one auxiliary sensor to an auxiliary power connection to sense at least one second electrical characteristic of the auxiliary power connection and to generate auxiliary sensor data;
coupling an analog-to-digital converter to the at least one main sensor and to the at least one auxiliary sensor for converting the main sensor data and the auxiliary sensor data from analog data to digital data; and
coupling a communication module to the analog-to-digital convert for communicating information based on the converted main sensor data and auxiliary sensor data to a user device.

19. The method of claim 18, wherein:
coupling the at least one main sensor to the main power connection comprises coupling a main current sensor to the main power connection; and
coupling the at least one auxiliary sensor to the auxiliary power connection comprises coupling an auxiliary current sensor to the auxiliary power connection.

20. The method of claim 18, further comprising coupling an antenna to the communication module to wirelessly communicate the information to the user device.
